(19) United States
(12) Patent Application Publication
(10) Pub. No.: US 2012/0055534 A1
(43) Pub. Date: Mar. 8, 2012

(54) Photovoltaic Devices with High Work-Function TCO Buffer Layers and Methods of Manufacture

(75) Inventors: Kurtis Leschkies, Santa Clara, CA (US); Roman Gouk, San Jose, CA (US); Steven Verhaverbeke, San Francisco, CA (US); Robert Visser, Menlo Park, CA (US)

(73) Assignee: Applied Materials, Inc., Santa Clara, CA (US)

(21) Appl. No.: 13/227,433

(22) Filed: Sep. 7, 2011

Related U.S. Application Data
(60) Provisional application No. 61/380,787, filed on Sep. 8, 2010.

(51) Int. Cl. H01L 31/042; H01L 31/0224; H01L 31/18; H01L 31/0216

(52) U.S. Cl. 136/244; 136/256; 438/98; 257/E31.119

(57) ABSTRACT

Embodiments of the invention are directed to photovoltaic cells comprising a substantially optically transparent buffer layer on a superstrate and a photoabsorber layer on the buffer layer. The buffer layer of detailed embodiments has a work function greater than or equal to about the work function of the photoabsorber layer. Additional embodiments of the invention are directed to photovoltaic modules comprises a plurality of photovoltaic cells and methods of making photovoltaic cells and photovoltaic modules.

### CROSS-REFERENCE TO RELATED APPLICATIONS

This application claims the benefit under 35 U.S.C. §119(e) of U.S. Provisional Application No. 61/380,787, filed Sep. 8, 2010.

### BACKGROUND

Embodiments of the present invention generally relate to photovoltaic cells, photovoltaic modules and methods of making the same. Specific embodiments pertain to photovoltaic cells comprising one or more of a substantially optically transparent buffer layer having a high work function and a substantially optically transparent blocking layer having a high charge blocking potential deposited adjacent a photoabsorber layer.

Transparent conducting electrodes based on metal oxides (e.g., Al-doped ZnO (AZO), indium doped SnO₂ (ITO) and fluorine dopes SnO₂ (FTO)) are common components in solar, display, and touchscreen technologies. These conducting electrodes provide low-resistance electrical contact while allowing unimpeded passage of light to and from the device's active layers. In the single- and tandem-junction Si solar technology, these metal oxides possess a number of disadvantages when placed in intimate contact with a p-type amorphous Si (a-Si) top layer that reduces the absolute efficiency of the solar cell.

The low work function (φ) of the metal oxide (φ˜4.3-4.9 eV) is often mismatched to the adjacent amorphous p-type Si layer (φ˜5.15 eV). This mismatch reduces the photovoltage in a device. An example of this mismatch is shown in FIG. 1, which illustrates a dark band diagram of a device in which an FTO layer is contacted with a p-i-n Si top cell. Contact of the FTO layer with the p-layer causes the work function of the materials to shift, and, consequently, the conduction and valence bands of the Si layer to bend to accommodate the TCO/p-layer equilibrium. This band bending may result in parasitic flow of electrons, meaning electrons flow in the wrong direction from the intrinsic layer toward the p-layer during normal solar cell operation when the applied bias to the cell is greater than 0 V.

To compensate for this work function mismatch, a heavily-doped thick microcrystalline p-type Si layer is often inserted to make ohmic contact with the metal oxide and shield the active amorphous Si junction layers from the low work function of the metal oxide to minimize photovoltage loss. In other words, the influence of the work function of the underlying metal oxide is minimized as the thickness of this microcrystalline layer is increased. However, this thick microcrystalline layer reduces the amount of blue light transmitted to the active amorphous Si layer and the amount of photocurrent extracted from the solar cell suffers as a result. Consequently, there is a photocurrent cost in adding this layer which is designed to preserve the photovoltage. Work function mismatch between the metal oxide (MO) and amorphous p-type Si layer also creates an electronic barrier at the metal oxide-p-Si interface that photogenerated holes must overcome to create a photocurrent. Those holes that cannot tunnel through this barrier recombine within the device. This leads to increased series resistance, reduced fill factor, and some additional reduced photocurrent in the device.

In addition to work function differences, the metal oxide is mismatched to amorphous p-Si in their refractive index (n) as well. Consequently, electromagnetic waves are reflected at the metal oxide-p-Si interface due to the refractive index transition from the metal oxide (n˜2) to the p-Si (n˜4), and is not absorbed by the Si active device.

Therefore, there is a need in the art for photovoltaic cells and methods of making photovoltaic cells with low-resistance electrical contacts that do not reduce the absolute efficiency of the cell.

### SUMMARY OF THE INVENTION

One or more embodiments of the present invention photovoltaic cells comprising a superstrate, one or more of a substantially optically transparent buffer layer having a work function and a substantially optically transparent blocking layer having a blocking potential, a photoabsorber layer and a back contact layer. The photoabsorber layer is in contact with the buffer layer or the blocking layer and has a work function. The back contact layer is on the photoabsorber layer. The buffer layer has a work function greater than or equal to about the work function of the photoabsorber layer.

Additional embodiments of the invention are directed to photovoltaic cells comprising a superstrate, a photoabsorber layer, one or more of a buffer layer and a blocking layer and a back contact layer. The photoabsorber layer has a work function. One or more of an optically transparent buffer layer having a work function and an optically transparent blocking layer having a blocking potential is on the photoabsorber layer. The back contact layer is on the one or more of the buffer layer and the blocking layer. The buffer layer has a work function that is less than or equal to about the work function of the photoabsorber layer adjacent the buffer layer.

Some embodiments further comprise a transparent conductive oxide layer between the superstrate and the buffer layer. In detailed embodiments, the transparent conductive oxide layer comprises one or more of aluminum doped zinc oxide and fluorine doped tin oxide.

In detailed embodiments, the buffer layer is selected from the group consisting of platinum, palladium, nickel, gallium indium oxide (GaInO₃), zinc stannate (ZnSnO₃), zinc indium tin oxide (ZITO), gallium indium tin oxide (GITO), tungsten nitride (WN), tungsten oxide (WO₃) metal oxide, metal nitride, fluorinated tin oxide (SnO₂:F), intrinsic zinc oxide (i-ZnO), calcium, magnesium, titanium oxide (TiOₓ) and combinations thereof.

In some embodiments, the work function of the buffer layer is greater than about 4.9 eV. In specific embodiments, the work function of the buffer layer is greater than about 5.05 eV.

The buffer layer in one or more embodiments has a has thickness up to about 50 nm. In detailed embodiments, the buffer layer has a thickness up to about 30 Å. In specific embodiments, the buffer layer comprises a metal nitride and has a thickness up to about 10 nm.

In some embodiments, the blocking layer is selected from the group consisting of tungsten oxide (WOₓ), nickel oxide, molybdenum oxide and combinations thereof.

The back contact layer in specific embodiments is a transparent conductive oxide.

Some embodiments of photovoltaic cell further comprise a reflective layer on the back contact layer.

One or more embodiments of the photovoltaic cell have a photoabsorber layer comprising a p-i-n junction. In detailed embodiments, the photoabsorber layer comprises an i-n junction formed from an i-layer and an p-layer, where the i-layer is deposited directly on the buffer layer.

In some embodiments, the photovoltaic cell further comprises one or more of a substantially optically transparent buffer layer and a substantially optically transparent blocking layer between the photoabsorber layer and the back contact layer.

Additional embodiments of the invention are directed to photovoltaic modules comprising a plurality of photovoltaic cells as described herein. In specific embodiments, the individual photovoltaic cells are connected in series.

Further embodiments of the invention are directed to methods of making a photovoltaic cell. One or more of a substantially optically transparent buffer layer having a work function and a substantially optically transparent blocking layer having a blocking potential are deposited on a superstrate. A photoabsorber layer is deposited on the one or more of the buffer layer and the blocking layer. The photoabsorber layer has a work function that is greater than or equal to about the work function of the photoabsorber layer. A back contact layer is deposited on the photoabsorber layer.

Some embodiments further comprise depositing a front contact layer on the superstrate before depositing one or more of the substantially optically transparent buffer layer and the substantially optically transparent blocking layer.

The layers of detailed embodiments are deposited by one or more of chemical vapor deposition, physical vapor deposition, atomic layer deposition, evaporation, or wet chemical solution processing. In specific embodiments, one or more of the buffer layer, blocking layer, photoabsorber layer and back contact layer are deposited by chemical vapor deposition.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a representative dark band diagram for a device having a fluorine doped tin oxide layer with a p-i-n silicon top cell;

FIG. 2 shows a representative dark band diagram for a device having a high work function buffer layer with a p-i-n silicon top cell;

FIG. 3 shows a photovoltaic cell in accordance with one or more embodiments of the invention;

FIG. 4 shows a photovoltaic cell in accordance with one or more embodiments of the invention;

FIG. 5 shows a photovoltaic cell in accordance with one or more embodiments of the invention;

FIG. 6 shows a photovoltaic cell in accordance with one or more embodiments of the invention;

FIG. 7 show an image of a photovoltaic cell in accordance with one or more embodiments of the invention;

FIG. 8 shows a graph of the current density as a function of voltage for photovoltaic cells in accordance with one or more embodiments of the invention; and

FIG. 9 shows a graph of the current density as a function of voltage for photovoltaic cells in accordance with one or more embodiments of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the singular forms “a”, “an” and “the” include plural referents unless the context clearly indicates otherwise. For example, reference to a “cell” may also refer to more than one cells, and the like.

The terms “photovoltaic cell” and “solar cell” are used to describe an individual stack of layers suitable for converting light energy into electricity. The terms “photovoltaic module” and “solar module” are used to describe a plurality of photovoltaic cells connected in series.

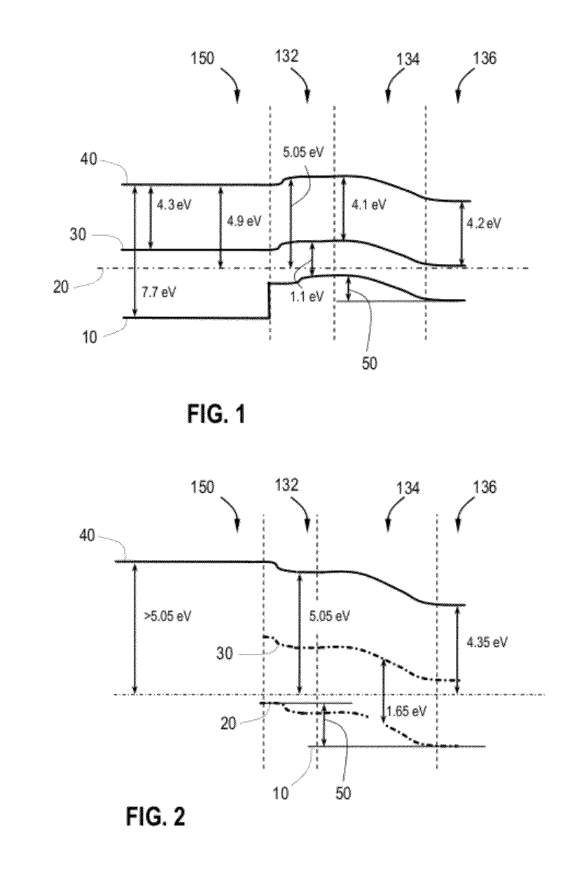

In many current photovoltaic devices, either fluorinated SnO₂ or aluminum doped ZnO is used for the a-Si single junction or tandem junction stack. Unfortunately, neither of these materials is perfectly matched to the p-Si top contact. The p-Si contact layer has a work function of about 5.05-5.15 eV. However, the SnO₂:F layer has a work function of about 4.9 eV. Therefore, a highly doped p-Si top contact is necessary to shield this low work function from the actual device junction. FIG. 1 illustrates a dark band diagram showing the Fermi level 10, the valence band 20, the conduction band 30, the vacuum level 40 and the built-in junction potential 50. Layers of the photovoltaic device shown are the front contact layer 150, the p-layer 132, the i-layer 134 and the n-layer 136. The built-in junction potential 50, the energy difference in the valence band between the n-layer 136 and the i-layer 134, of the cell shown in FIG. 1 is about 0.8 to about 0.9 volts. It can be seen that the energy levels of the valence band 20, the conduction band 30 and the vacuum level 40 are pulled downward as the levels transition from the p-layer 132 to the front contact layer 150.

It may be desirable to keep the p-layer as thin as possible, since all light absorbed in the p-layer is lost for carrier generation and collection. This can be seen as a decrease in the device current when making the p-layer thicker.

When using SnO₂:F as the Transparent Conductor, there are some drawback such as darkening due to reduction of SnO₂ to Sn when exposed to a hydrogen plasma and the mismatch of the index of refraction with silicon. In order to address these issues, TiO₂ (with Nb doping to increase the conductivity of insulating TiO₂) is sometimes added as an extra layer on top of SnO₂:F. This buffer layer improves the index of refraction transition and reduces the SnO₂ darkening. However, Nb doped TiO₂ has a much lower work function than SnO₂:F and hence does not match very well with the p-doped Si to which it has to contact. The work function of TiO₂ is about 4.45 eV, far from a good match with p-Si. Therefore, the Voc will drop whenever such a low work function buffer layer is used and the work function will drop as a function of thickness of the TiO₂:Nb layer.

Alternatively to SnO₂:F, aluminum-doped ZnO can be used. Aluminum-doped has the advantage that it can be textured to much higher hazes levels than SnO₂:F which leads to better light trapping. ZnO:Al also has the advantage that it it's conductivity is higher than SnO₂:F and hence less resistive losses are experienced or wider cells can be made. Also ZnO:Al has less darkening because it is more stable in a hydrogen plasma than SnO₂:F and is harder to reduce to metallic Zn.

However, ZnO:Al has the disadvantage to SnO₂:F that it's work function is lower and hence less matched with the p-Si contact. The work function of ZnO:Al is about 4.4-4.7 eV and far from matched with the 5.05-5.15 eV of the p-Si. Since this mismatch is so large, even doping the a-Si to high levels does not provide for a good contact and the only way to get a good contact with ZnO:Al is to insert a μ-crystalline highly doped p-layer.

Therefore, it is believed that a high work function buffer layer between the ZnO:Al and the p-Si, which provides good contact, will increase Voc and therefore reduce the p-layer thickness, removing the need for an extra μ-crystalline p-layer. A buffer layer with a work function higher than the work function of the p-layer will drive the electrical band bending toward the p-layer, decreasing voltage loss due to contact with the p-layer. The buffer layer should also decrease the contact resistance and therefore could increase the Fill Factor. Additionally, if the contacting buffer layer has a higher work function that the p-Si it contacts, the p-Si can be reduced substantially in thickness or can be eliminated altogether and a Shottky-contact can be employed, which reduces the likelihood of electrons moving from the p-layer toward the TCO layer. This would have the benefit that even higher Vocs are possible than what are possible with a p-Si electrode.

FIG. 2 shows a dark band diagram of a high work function front contacting buffer layer in contact with the p-layer. The built-in junction potential 50 of the embodiment represented in FIG. 2 is about 1.07 to about 1.3 volts. The Fermi level 10, valence band 20, conduction band 30 and vacuum levels 40 are shown for the front contact 150, p-layer 132, i-layer 134 and n-layer 136 of the photoabsorber. The work function, defined as the difference between the vacuum level and the Fermi level (E_{f}) for relevant regions is shown. The electron affinity and band gap at various locations in the device are shown as well. The electron affinity is the difference between the vacuum level and the conduction band. The band gap is the difference between the conduction band and the valence band. FIG. 2 shows a work function in the front contact layer to be greater than the work function in the photoabsorber region.

One or more embodiments of the invention are directed to photovoltaic cells and photovoltaic modules with a thin buffer layer inserted between a conductive metal oxide layer and p-type Si layer. The buffer layer of one or more embodiments has one or more of the following properties: (a) a high work function (>5.15 eV); (b) is optically transparent; (c) is resistant to hydrogen plasma; (d) is electrically conductive; (e) makes good contact to amorphous p-Si; and/or (f) has a refractive index matched to the conductive metal oxide and p-Si.

Without being bound by any particular theory of operation, it is believed that a buffer layer having some or all of these characteristics would provide the benefit of improving the photovoltage in the solar cell by pulling the Fermi level of the p-type a-Si up with respect to the vacuum level (as opposed to down with the metal oxide) and much closer to the conduction band edge, thereby increasing the built-in potential in the device (>50% relative increase). Additionally, the buffer layer would allow one to eliminate the microcrystalline p-type “shield” layer, use a much thinner active p-layer in the p-i-n top cell, or perhaps eliminate the need for an active p-layer altogether. Eliminating the p-layer completely would provide the following benefits: (a) reduce CVD processing time; (b) allow the i-Si layer to be deposited at much higher temperatures (˜300° C.) leading to both a higher quality active layer and reduced light induced degradation as a result of defects; and/or (c) lower the cost of the solar cell. In the latter case, the buffer layer and i-Si could form a Schottky contact during solar cell operation. Additional potential benefits may include increased photocurrents by reducing reflection losses with enhanced refractive index matching between the metal oxide and p-Si, and a decrease/increase in series resistance/fill factor through the work function matching and good adhesion properties to p-Si.

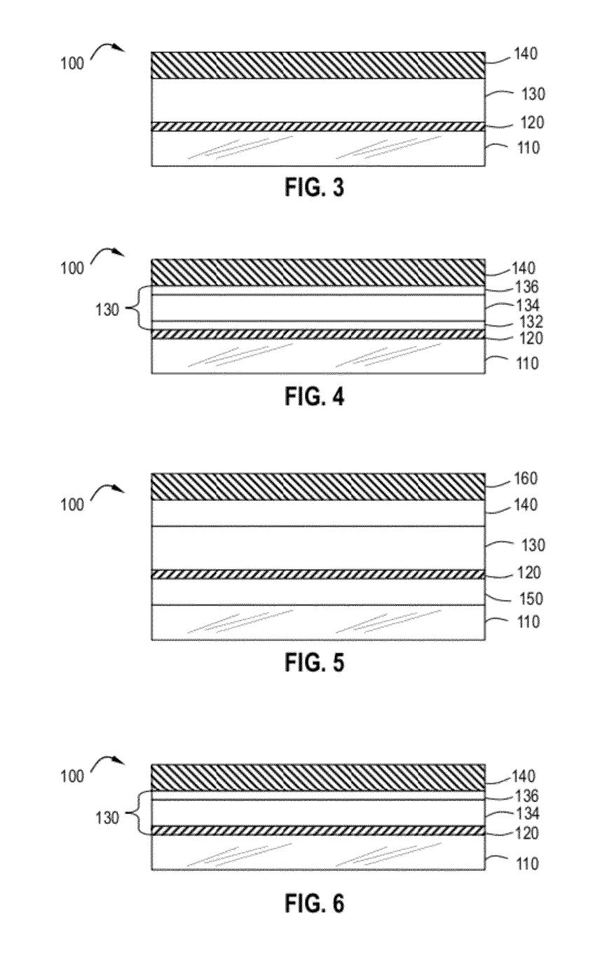

With reference to FIGS. 3 through 6, one or more embodiments of the invention are directed to photovoltaic cells 100. The photovoltaic cells 100 comprise a superstrate 110, sometimes referred to as a substrate. Various layers are deposited on the superstrate 110, which becomes the surface that faces the light. The superstrate 110 can be made from any suitable material including, but not limited to, glass and plastic. The superstrate 110 should allow substantially all light which can be absorbed by a photoabsorber layer 130 to pass through.

A substantially optically transparent buffer layer 120 is deposited on the superstrate 110. The optically transparent buffer layer 120 can be deposited directly on the superstrate 110, or there can be one or more intervening layers. As used in this specification and the appended claims, the term “substantially optically transparent” means that less than about 5% of usable light is absorbed or reflected by the buffer layer 120. The buffer layer 120 can be deposited by any suitable techniques including, but not limited to, physical vapor deposition (PVD), chemical vapor deposition (CVD), atomic layer deposition (ALD) (also called atomic layer epitaxy), evaporation (such as electron beam or ion-beam assisted), and/or processing from liquid solution precursors. In specific embodiments, the buffer layer 120 is deposited by PVD. In detailed embodiments, the buffer layer 120 is deposited by CVD. In some embodiments, the buffer layer 120 is deposited by ALD. In some embodiments, the buffer layer 120 is deposited by evaporation methods. In some embodiments, the buffer layer 120 is deposited by wet chemical processing.

In detailed embodiments, the buffer layer 120 is selected from the group consisting of platinum, palladium, nickel, gallium indium oxide (GaInO3), zinc stannate (ZnSnO₃), zinc indium tin oxide (ZITO), gallium indium tin oxide (GITO), tungsten nitride (WN), metal nitride, fluorinated tin oxide (SnO₂:F), intrinsic zinc oxide (i-ZnO) and combinations thereof.

The work function of the buffer layer 120 can serve to enhance the built-in junction potential of the resultant photovoltaic cell. The work function of the buffer layer 120 in some embodiments is greater than about 4.9 eV. In detailed embodiments, the work function of the buffer layer is greater than about 5.05 eV. In various embodiments, the work function of the buffer layer is greater than about 4.95 eV, 5.0 eV, 5.1 eV, 5.15 eV, 5.2 eV, 5.25 eV, 5.3 eV, 5.35 eV, 5.4 eV, 5.45 eV, 5.5 eV, 5.55 eV, 5.6 eV, 5.65 eV, 5.7 eV, 5.75 eV, 5.8 eV, 5.85 eV, 5.9 eV, 5.95 eV, 6.0 eV, 6.05 eV, or 6.1 eV.

The thickness of the buffer layer 120 may have an impact on both the work function and transparency depending on the material selected for the buffer layer 120. In some embodiments, the buffer layer 120 has a thickness up to about 50 nm. In detailed embodiments, the buffer layer 120 has a thickness up to about 30 Å. This may be especially useful where the buffer layer 120 is made up of a metal such as platinum or palladium. In specific embodiments, the buffer layer 120 comprises a metal nitride and has a thickness less than about 10 nm. In various embodiments the buffer layer 120 has a thickness up to about 10 Å, 15 Å, 20 Å, 25 Å, 1 nm, 2 nm, 3 nm, 4 nm, 5 nm, 10 nm, 15 nm, 20 nm, 25 nm, 30 nm, 35 nm, 40 nm or 45 nm.

In some embodiments, the substantially optically transparent blocking layer is deposited either in place of or in addition to the buffer layer 120. As used throughout this specification, where the term “buffer layer” can also be understood to mean one or more of a buffer layer and a blocking layer. The blocking layer has a blocking potential. The blocking layer may or may not have a high work function as it shields the photoabsorber layer from the work function of a superstrate or transparent conductive oxide layer adjacent the p-layer. In some embodiments, the blocking layer has both a high work function and a high blocking potential. In some embodiments, the blocking layer is selected from the group consisting of tungsten oxide (WOₓ, wherein x is in the range of 0 and 5), nickel oxide, molybdenum oxide and combinations thereof. In specific embodiments, the blocking layer comprises tungsten oxide. Without being bound by any particular theory of operation, it is believed that the blocking layer helps maximize charge by reducing the impact of the work function of the front contact on the work function of the photoabsorber layer.

The thickness of the blocking layer depends on the material selected. In some embodiments, the blocking layer has a thickness up to about 50 nm. In detailed embodiments, the blocking layer has a thickness up to about 30 Å. In specific embodiments, the blocking layer comprises a metal oxide and has a thickness less than about 10 nm. In various embodiments the blocking layer has a thickness up to about 10 Å, 15 Å, 20 Å, 25 Å, 1 nm, 2 nm, 3 nm, 4 nm, 5 nm, 10 nm, 15 nm, 20 nm, 25 nm, 30 nm, 35 nm, 40 nm or 45 nm.

In embodiments where both a buffer layer and a blocking layer are employed, the thickness of each layer can be tuned separately. The total thickness of the combined layers in various embodiments, is up to about 10 Å, 15 Å, 20 Å, 25 Å, 1 nm, 2 nm, 3 nm, 4 nm, 5 nm, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm or 100 nm.

A photoabsorber layer 130 is deposited on the buffer layer 120 and/or blocking layer. The photoabsorber layer 130 has a work function which is less than or equal to about the work function of the buffer layer. Put another way, the buffer layer 120 has a work function greater than or equal to about the work function of the photoabsorber layer 130. As shown in FIG. 4, the photoabsorber layer can be made up of a combination of individual layers. For example, a single junction photovoltaic cell may include a p-layer 132 adjacent the buffer layer 120, an intrinsic layer 134 on the p-layer 132 and an n-layer 136 on the intrinsic layer 134. In tandem junction photovoltaic modules, a separate p-i-n layer is deposited over the p-i-n layers shown in FIG. 4. The photoabsorber layer 130, including the individual layers, can be deposited by any suitable techniques including, but not limited to, PVD, CVD, ALD, evaporation, or wet chemical processing. In specific embodiments, the photoabsorber layer 130 or individual layers are deposited by PVD. In detailed embodiments, the photoabsorber layer 130 or individual layers are deposited by CVD. In some embodiments, the photoabsorber layer 130 or individual layers are deposited by ALD. In some embodiments, the photoabsorber layer 130 or individual layers are deposited by evaporation techniques. In some embodiments, the photoabsorber layer 130 or individual layers are deposited by wet chemical processing methods.

The thickness of individual layers of the photoabsorber layer 130 can be adjusted depending on the desired properties of the resultant photovoltaic cell. In some embodiments the p-layer 132 has a thickness in the range of about 5 to about 20 nm, or in the range of about 8 to about 15 nm. Minimizing the thickness of the p-layer 132 increases the efficiency of the resultant solar cell because light absorbed in the p-layer is lost for carrier generation and collection. In some embodiments, the i-layer 134, or intrinsic layer, has a thickness in the range of about 10 to about 20 times the thickness of the p-layer 132. In various embodiments, the thickness of the i-layer 134 is about 50 nm, 100 nm, 150 nm, 200 nm, 250 nm, 300 nm, 350 nm or 400 nm. The n-layer 136 thickness is often about the same as the p-layer 132 thickness. In some embodiments the n-layer 136 has a thickness in the range of about 5 to about 20 nm, or in the range of about 8 to about 15 nm.

In specific embodiments, as shown in FIG. 5, the photovoltaic cell 100 further comprises a transparent conductive oxide layer 150 located between the superstrate 110 and the buffer layer 120. In detailed embodiments, the transparent conductive oxide layer comprises aluminum doped zinc oxide. In some embodiments, the transparent conductive oxide layer comprises fluorine doped tin oxide.

The buffer layer 120 may have any of a multitude of characteristics. Some buffer layer 120 materials make good adhesion to the p-layer 132 of the photoabsorber layer 130. The buffer layer 120 may be made of a material that resists damage from a hydrogen plasma. The buffer layer 120 of some embodiments has a refractive index that is substantially matched to one or more of a transparent conductive oxide 150 layer and the p-layer 132 of the photoabsorber layer 130.

Insertion of a high work function buffer layer 120 between a transparent conductive oxide layer 150 and the photoabsorber layer 130 may allow for the reduction in the thickness of the p-layer 132. In specific embodiments, as shown in FIG. 6, the p-layer 132 is eliminated from the photoabsorber layer 130. Elimination of the p-layer 132 allows for reduced processing costs and enhanced light absorption. Additionally, elimination of the p-layer 132 may form a Schottky contact between the high work function buffer layer 120 and the i-layer 134 in a p-i-n device.

A back contact layer 140 is deposited on the photoabsorber layer 130 or combination of individual layers which make up the photoabsorber layer 130. The back contact layer 140, which may also be referred to as a back contact stack, may include individual layers which serve various purposes. Some layers may reflect light not absorbed by the photoabsorber layer 130, providing the photoabsorber layer 130 a second chance to absorb the reflected light. In some embodiments, the back contact layer 140 includes at least one sublayer which can act as a back electrode which allows the photovoltaic cell to be connected to adjacent photovoltaic cells. The back contact layer 140 may also include one or more of passivation layers and a substrate. In specific embodiments the back contact layer 140 is a transparent conductive oxide or includes a transparent conductive oxide. In detailed embodiments, the photovoltaic cell 100 further comprises a reflective layer 160 on the back contact layer 140 or as part of the back contact stack.

Additional embodiments of the invention are directed to photovoltaic modules comprising a plurality of photovoltaic cells as previously described. In specific embodiments the individual photovoltaic cells are connected in series.

Further embodiments of the invention are directed to photovoltaic cells having a buffer layer and/or blocking layer on the n-layer side of the p-i-n junction. In these embodiments, the buffer layer would have a lower work function than the n-layer to avoid electrical band bending which may cause electrons to flow from the n-layer to the i-layer of the photoabsorber. In specific embodiments, the buffer layer on the n-layer side is made of one or more of calcium, magnesium, and titanium oxide (TiOx). In detailed embodiments the buffer layer is highly reflective.

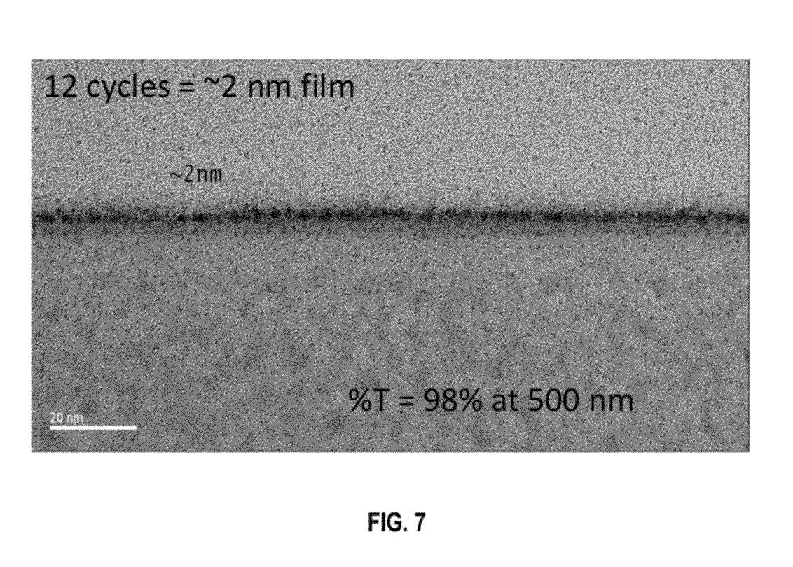

FIG. 7 shows an image of a thin WN/WO layer deposited by MOCVD with C₁₂H₃₀N₄W and N₂ remote plasma. The deposition temperature was 525° C. and the resultant film thickness was about 2 nm after 12 CVD cycles. The average solar flux weighted transmission was about 98% for this layer.

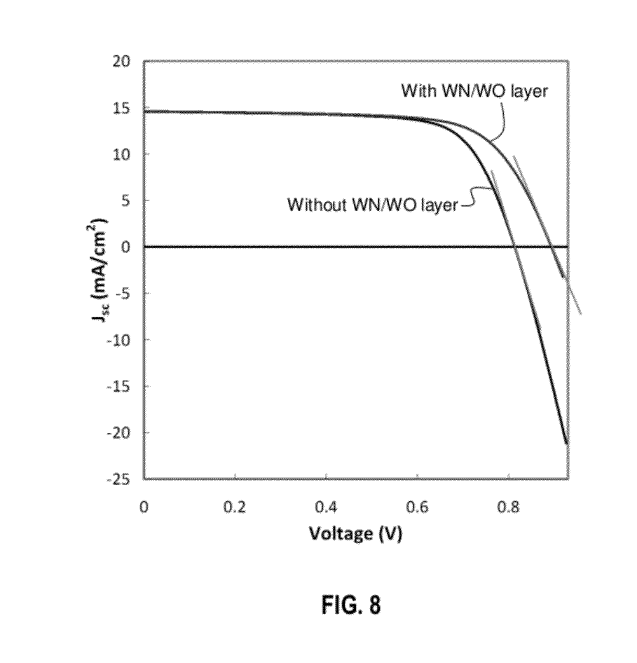

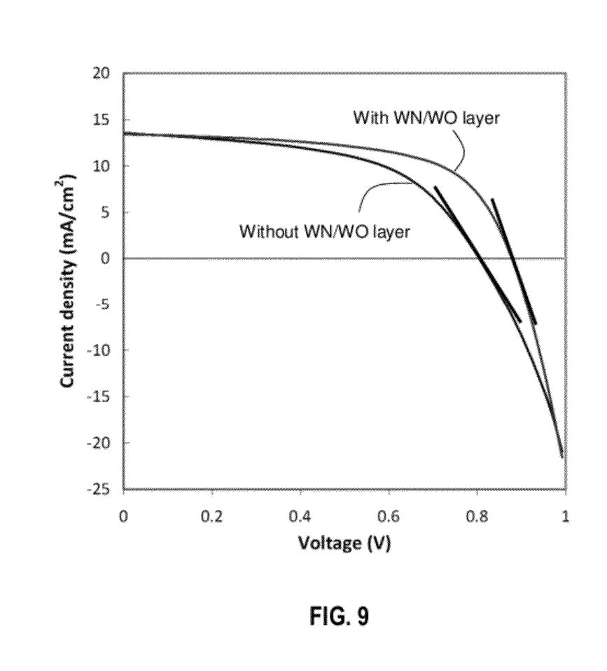

FIGS. 8 and 9 show J-V characteristics measured in light at an illumination of about 100 mW/cm². The graph of FIG. 8 was obtained for solar cells based on the following stack: FTO substrate-about 2 nm WN/WO film-p-i-n a-Si-AZO-Al. The p-, i- and n-layers were all based on a-Si. The graph of FIG. 9 was obtained for solar cell based on the following stack: AZO substrate-about 2 nm WN/WO film-p-i-n a-Si layer-AZO-Al. The p-layer in this cell was based on microcrystalline a-Si, while the i- and n-layers were a-Si. The WN/WO layers were deposited in the same manner as that of FIG. 7 (MOCVD). The silicon layers were produced using PECVD and the AZO/Al back contact using PVD. It can be seen from FIG. 8 that the voltage of the solar cell on FTO substrate with the WN/WO layer was enhanced. It can be seen from FIG. 9 that both the fill factor (as shown by the steeper slope) and the voltage was enhanced with AZO substrate with the WN/WO layer.

Reference throughout this specification to “one embodiment,” “certain embodiments,” “one or more embodiments,” “an embodiment,” “one aspect,” “certain aspects,” “one or more embodiments” and “an aspect” means that a particular feature, structure, material, or characteristic described in connection with the embodiment is included in at least one embodiment of the invention. Thus, the appearances of the phrases such as “in one or more embodiments,” “in certain embodiments,” “in one embodiment,” “in an embodiment,” “according to one or more aspects,” “in an aspect,” etc., in various places throughout this specification are not necessarily referring to the same embodiment or aspect of the invention. Furthermore, the particular features, structures, materials, or characteristics may be combined in any suitable manner in one or more embodiments or aspects. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A photovoltaic cell comprising:
a superstrate;
one or more of a substantially optically transparent buffer layer having a work function and a substantially optically transparent blocking layer having a blocking potential;
a photoabsorber layer in contact with the buffer layer or the blocking layer, the photoabsorber layer having a work function; and
a back contact layer on the photoabsorber layer,
wherein the buffer layer has a work function greater than or equal to about the work function of the photoabsorber layer.

2. The photovoltaic cell of claim 1, further comprising a transparent conductive oxide layer between the superstrate and the buffer layer.

3. The photovoltaic cell of claim 2, wherein the transparent conductive oxide layer comprises one or more of aluminum doped zinc oxide and fluorine doped tin oxide.

4. The photovoltaic cell of claim 1, wherein the buffer layer is selected from the group consisting of platinum, palladium, nickel, gallium indium oxide (GaInO₃), zinc stannate (ZnSnO₃), zinc indium tin oxide (ZITO), gallium indium tin oxide (GITO), tungsten nitride (WN), tungsten oxide (WO₃) metal oxide, metal nitride, fluorinated tin oxide (SnO₂:F), intrinsic zinc oxide (i-ZnO) and combinations thereof.

5. The photovoltaic cell of claim 1, wherein the blocking layer is selected from the group consisting of tungsten oxide (WOₓ), nickel oxide, molybdenum oxide and combinations thereof.

6. The photovoltaic cell of claim 1, wherein the work function of the buffer layer is greater than about 4.9 eV.

7. The photovoltaic cell of claim 1, wherein the work function of the buffer layer is greater than about 5.05 eV.

8. The photovoltaic cell of claim 1, wherein the buffer layer has a thickness up to about 50 nm.

9. The photovoltaic cell of claim 1, wherein the buffer layer comprises a metal nitride and has a thickness up to about 10 nm.

10. The photovoltaic cell of claim 1, wherein the back contact layer is a transparent conductive oxide.

11. The photovoltaic cell of claim 1, wherein the photoabsorber layer comprises a p-i-n junction.

12. The photovoltaic cell of claim 1, wherein the photoabsorber layer comprises an i-n junction formed from an i-layer and an n-layer, where the i-layer is deposited directly on the buffer layer.

13. The photovoltaic cell of claim 1, further comprising one or more of a substantially optically transparent buffer layer and a substantially optically transparent blocking layer between the photoabsorber layer and the back contact layer.

14. A photovoltaic module comprising a plurality of photovoltaic cells according to claim 1.

15. A method of making a photovoltaic cell comprising:
depositing one or more of a substantially optically transparent buffer layer having a work function and a substantially optically transparent blocking layer having a blocking potential on a superstrate;
depositing a photoabsorber layer on the one or more of the buffer layer and the blocking layer, the photoabsorber layer having a work function; and
depositing a back contact layer on the photoabsorber layer,
wherein the buffer layer has a work function greater than or equal to about the work function of the photoabsorber layer.

16. The method of claim 15, further comprising depositing a front contact layer on the superstrate before depositing one or more of the substantially optically transparent buffer layer and the substantially optically transparent blocking layer.

17. The method of claim 15, wherein the buffer layer is selected from the group consisting of platinum, palladium, nickel, gallium indium oxide (GaInO₃), zinc stannate (ZnSnO₃), zinc indium tin oxide (ZITO), gallium indium tin oxide (GITO), tungsten nitride (WN), metal nitride, fluorinated tin oxide (SnO₂:F), intrinsic zinc oxide (i-ZnO) and combinations thereof.

18. The method of claim 15, wherein the buffer layer has a thickness up to about 50 nm.

19. A photovoltaic cell comprising:
a superstrate;
a photoabsorber layer having a work function;
one or more of an optically transparent buffer layer having a work function and an optically transparent blocking layer having a blocking potential on the photoabsorber layer; and
a back contact layer on the one or more of the buffer layer and the blocking layer,
wherein the buffer layer has a work function less than or equal to about the work function of the photoabsorber layer adjacent the buffer layer.

20. The method of claim 19, wherein the buffer layer comprises one or more of calcium, magnesium and titanium oxide.
